(19) United States
(12) Patent Application Publication
(10) Pub. No.: US 2021/0027995 A1
(43) Pub. Date: Jan. 28, 2021

(54) FOCUS RING AND SUBSTRATE TREATING APPARATUS COMPRISING THE SAME

(71) Applicant: SEMES CO., LTD., Chungcheongnam-do (KR)

(72) Inventors: Dongmok Lee, Chungcheongnam-do (KR); Sang-Kee Lee, Chungcheongnam-do (KR)

(21) Appl. No.: 16/924,516

(22) Filed: Jul. 9, 2020

(30) Foreign Application Priority Data
Jul. 22, 2019 (KR) 10-2019-0088070

(51) Int. Cl. H01J 37/32; H01L 21/3065

(52) U.S. Cl. CPC H01J 37/32642; H01L 21/3065; H01J 2237/334; H01J 37/32082; H01J 37/32724

(57) ABSTRACT

Provided is a focus ring and a substrate treating apparatus having the focus ring. The substrate treating apparatus includes a process chamber for providing a process treating space for a substrate, a chuck for supporting the substrate and a focus ring arranged to surround an edge of the chuck, wherein the focus ring includes a plurality of layers having different properties, wherein a bonding surface between the plurality of layers is formed in a predetermined pattern.

### CROSS-REFERENCE TO RELATED APPLICATIONS

This patent application claims the benefit of Korean Patent Application No. 10-2019-0088070, filed on Jul. 22, 2019, which is hereby incorporated by reference in its entirety into this application.

### BACKGROUND

### 1. Field

The present invention relates to a focus ring and a substrate treating apparatus comprising the focus ring.

### 2. Description of the Related Art

When manufacturing a semiconductor device or a display device, various processes such as photography, etching, ashing, ion implantation, thin film deposition and cleaning are performed. Here, the photography process includes coating, exposure and development processes. A photoresist is applied onto the substrate (i.e., the coating process), a circuit pattern is exposed on the substrate, on which the photosensitive film is formed (i.e., exposure process), and the exposed areas of the substrate are selectively developed (i.e., development process).

In general, plasma may be used to etch a thin film formed on a wafer or substrate in a semiconductor manufacturing process. Etching of the thin film may be performed by the plasma colliding with the wafer or the substrate by an electric field formed inside the process chamber.

A ring member may be provided along the edge of the wafer or substrate to increase the concentration of plasma concentrated at the edge of the wafer or substrate. Plasma is concentrated on the edge of the wafer or substrate by the ring member so that high-quality etching of the edge as well as the central portion of the wafer or substrate can be performed.

### SUMMARY

The problem to be solved by the present invention is to provide a focus ring and a substrate treating apparatus comprising the focus ring.

The problems of the present invention are not limited to the problems mentioned above, and other problems not mentioned will be clearly understood by those skilled in the art from the following description.

One aspect of the substrate treating apparatus of the present invention for achieving the above object comprises a process chamber for providing a process treating space for a substrate, a chuck for supporting the substrate, and a focus ring arranged to surround an edge of the chuck, the focus ring includes a plurality of layers having different properties and a bonding surface between the plurality of layers is formed in a predetermined pattern.

The plurality of layers includes a protective layer that is a top layer among the plurality of layers and made of a material having an etching resisting property and an electrostatic power generating layer that is arranged under the protective layer and made of material generating an electrostatic power.

The protective layer is made of a material of silicon carbide (SiC), alumina (Al₂O₃), yttria (Y₂O₃), or aluminum nitride (AlN).

The electrostatic power generating layer is made of a material of silicon (Si).

The electrostatic power generating layer is made of a material having a higher dielectric constant than the protective layer.

The electrostatic power generating layer is one layer or includes a plurality of layers having different dielectric constants.

The bonding surface between the plurality of layers has a shape inclined with respect to the ground.

The bonding surface has a shape inclined with respect to ground such that a thickness of one of the plurality of layers decreases as it moves away from the substrate, and a thickness of another one of the plurality of layers increases as it moves away from the substrate.

The bonding surface is a flat surface or a curved surface.

One aspect of a focus ring of the present invention for achieving the above object comprises a protective layer that is arranged to surround an edge of a chuck supporting a substrate, has a ring shape, and is made of a material having an etching resisting property, and an electrostatic power generating layer that is arranged under the protective layer, has a ring shape, and is made of material generating an electrostatic power, wherein a bonding surface between the protective layer and the electrostatic power generating layer is formed in a predetermined pattern.

The protective layer is made of a material of silicon carbide (SiC), alumina (Al₂O₃), yttria (Y₂O₃), or aluminum nitride (AlN).

The electrostatic power generating layer is made of a material of silicon (Si).

The electrostatic power generating layer is made of a material having a higher dielectric constant than the protective layer.

The electrostatic power generating layer is one layer or includes a plurality of layers having different dielectric constants.

The bonding surface has a shape inclined with respect to the ground.

The bonding surface has a shape inclined with respect to ground such that a thickness of one of the protective layer and the electrostatic power generating layer decreases as it moves away from the substrate, and a thickness of another one of the protective layer and the electrostatic power generating layer increases as it moves away from the substrate.

The bonding surface is a flat surface or a curved surface.

Another aspect of a substrate treating apparatus of the present invention for achieving the above object comprises a process chamber for providing a process treating space for a substrate, a chuck for supporting the substrate and a focus ring arranged to surround an edge of the chuck, wherein the focus ring includes a plurality of layers having different properties, wherein a bonding surface between a plurality of layers has a shape inclined with respect to ground so as to be determined in a direction to mitigate change of an electric field that changes as the focus ring is etched.

The bonding surface has a shape inclined with respect to ground such that a thickness of one of the plurality of layers decreases as it moves away from the substrate, and a thickness of another one of the plurality of layers increases as it moves away from the substrate.

The bonding surface is a flat surface or a curved surface.

Details of other embodiments are included in the detailed description and drawings.

### BRIEF DESCRIPTION OF THE DRAWINGS

FIG. 1 is a diagram showing a substrate treating apparatus according to an embodiment of the present invention.

FIG. 2 is a diagram showing a focus ring shown in FIG. 1.

FIG. 3 is a diagram showing a cross-section of the focus ring shown in FIG. 2.

FIGS. 4 to 7 are diagrams showing cross-sections of a focus ring according to another embodiment of the present invention.

### DETAILED DESCRIPTION

Hereinafter, preferred embodiments of the present invention will be described in detail with reference to the accompanying drawings. Advantages and features of the present invention, and methods for achieving them will be clarified with reference to embodiments described below in detail together with the accompanying drawings. However, the present invention is not limited to the embodiments disclosed below, but may be implemented in various different forms, and only the embodiments allow the publication of the present invention to be complete, and are provided to fully inform those skilled in the technical field to which the present invention pertains of the scope of the invention, and the invention is only defined by the scope of the claims. The same reference numerals refer to the same components throughout the specification.

When elements or layers are referred to as “on” or “above” of other elements or layers, it includes not only when directly above of the other elements or layers, but also other layer or other element intervened in the middle. On the other hand, when elements are referred to as “directly on” or “directly above,” it indicates that no other element or layer is intervened therebetween.

The spatially relative terms “below,” “beneath,” “lower,” “above,” “upper,” etc., as shown in figures, can be used to easily describe the correlation of an element or components with other elements or components. The spatially relative terms should be understood as terms including the different direction of the element in use or operation in addition to the direction shown in the drawing. For example, if the element shown in the figure is turned over, an element described as “below” or “beneath” the other element may be placed “above” the other element. Accordingly, the exemplary term “below” can include both the directions of below and above. The element can also be oriented in other directions, so that spatially relative terms can be interpreted according to the orientation.

Although the first, second, etc. are used to describe various elements, components and/or sections, these elements, components and/or sections are not limited by these terms. These terms are only used to distinguish one element, component or section from another element, component or section. Therefore, the first element, first component or first section mentioned below may be a second element, second component or second section within the technical spirit of the present invention.

The terminology used herein is for describing the embodiments and is not intended to limit the present invention. In the present specification, the singular form also includes the plural form unless otherwise specified in the phrase. As used herein, “comprises” and/or “comprising” means that the components, steps, operations and/or elements mentioned above do not exclude the presence or additions of one or more other components, steps, operations and/or elements.

Unless otherwise defined, all terms (including technical and scientific terms) used in the present specification may be used as meanings commonly understood by those skilled in the art, to which the present invention pertains. In addition, terms defined in the commonly used dictionary are not ideally or excessively interpreted unless specifically defined.

Hereinafter, exemplary embodiments of the present invention will be described in detail with reference to the accompanying drawings, and in the description with reference to the accompanying drawings, the same or corresponding components are assigned the same reference numbers regardless of reference numerals, and the description overlapped therewith will be omitted.

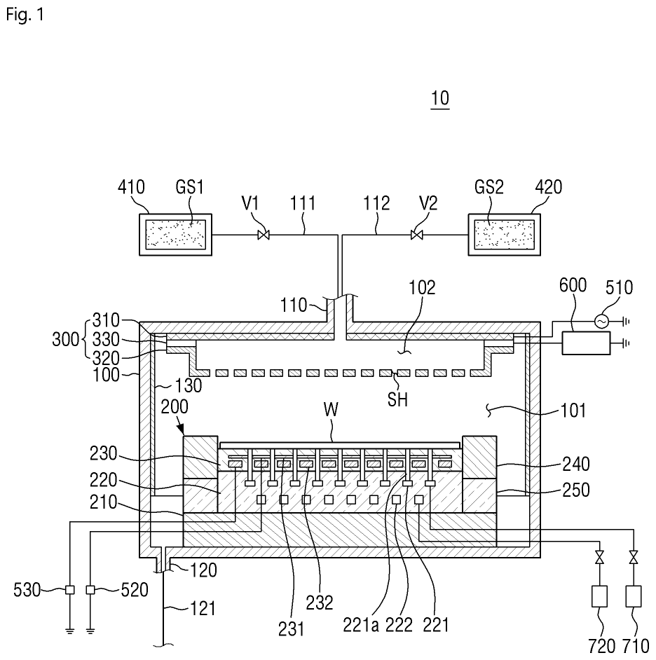

FIG. 1 is a diagram showing a substrate treating apparatus according to an embodiment of the present invention.

Referring to FIG. 1, the substrate treating apparatus 10 includes a process chamber 100, a substrate supporting unit 200, a shower head 300, a first gas tank 410, a second gas tank 420, a first power supplying unit 510, a second power supplying unit 520, a third power supplying unit 530, a heater 600, a heat medium supplying unit 710 and a refrigerant supplying unit 720.

The process chamber 100 provides a treating space 101 of the substrate W. The outlet 120 may be provided on the bottom surface of the process chamber 100. The outlet 120 is connected to the outlet line 121. By-products and gases generated during the process treating for the substrate W may be emitted to the outside through the outlet 120 and the outlet line 121.

A liner 130 may be provided inside the process chamber 100. The liner 130 prevents the inner surface of the process chamber 100 from being damaged by an arc discharge, and prevents impurities generated during the process for the substrate W from being deposited in the process chamber 100. To this end, the liner 130 may be attached to the inner surface of the process chamber 100 to surround the substrate supporting unit 200.

The substrate supporting unit 200 serves to support the substrate W. The substrate supporting unit 200 may be arranged in the lower part of the treating space 101.

The substrate supporting unit 200 includes a base plate 210, a main body 220, a chuck 230, a focus ring 240 and a ring support 250.

The base plate 210 serves to support the main body 220, the chuck 230, the focus ring 240 and the ring support 250. The base plate 210 may be an insulator.

The main body 220 may be provided between the base plate 210 and the chuck 230. A heat medium circulation tube 221 and a refrigerant circulation tube 222 may be provided inside the main body 220. The heat medium may be circulated through the heat medium circulation tube 221, and the refrigerant may be circulated through the refrigerant circulation tube 222. The heat medium circulation tube 221 and the refrigerant circulation tube 222 may be arranged in a spiral shape inside the main body 220. The main body 220 may be heated as the heat medium circulates through the heat medium circulation tube 221, and the main body 220 may be cooled as the refrigerant circulates through the refrigerant circulation tube 222.

The main body 220 may be made of metal. The chuck 230 in close contact with the main body 220 may be affected by the temperature of the main body 220. The chuck 230 may be heated as the main body 220 is heated, and the chuck 230 may be cooled as the main body 220 is cooled.

A heat medium supplying tube 221a for supplying heat medium to the upper part of the chuck 230 may be connected to the heat medium circulation tube 221. The heat medium may be supplied to the substrate W through the heat medium supplying tube 221a.

The heat medium supplying unit 710 may supply heat medium to the heat medium circulation tube 221, and the refrigerant supplying unit 720 may supply refrigerant to the refrigerant circulation tube 222. In the present invention, the heat medium may be helium gas as an inert gas, but the heat medium of the present invention is not limited to helium gas.

The chuck 230 serves to support the substrate W. In the present invention, the chuck 230 may be an electrostatic chuck. That is, the chuck 230 can adsorb the substrate W with electrostatic power. However, the chuck 230 of the present invention is not limited to the electrostatic chuck, and the chuck 230 may also hold and support the substrate W in a mechanical manner. Hereinafter, it will be mainly described focusing on that the chuck 230 is an electrostatic chuck.

The body of the chuck 230 may be dielectric. An electrostatic electrode 231 and a heating unit 232 may be provided inside the chuck 230. The electrostatic electrode 231 may be electrically connected to the second power supplying unit 520. The electrostatic electrode 231 may generate electrostatic power by the power supplied from the second power supplying unit 520. The substrate W may be adsorbed to the chuck 230 by the electrostatic power.

The heating unit 232 may be electrically connected to the third power supplying unit 530. The heating unit 232 may be heated by power supplied from the third power supplying unit 530. The heat of the heating unit 232 may be transferred to the substrate W. The substrate W may be maintained at a constant temperature by the heat of the heating unit 232. The heating unit 232 may be provided in the form of a coil and arranged in a spiral shape inside the chuck 230.

The second power supplying unit 520 may supply power to the electrostatic electrode 231, and the third power supplying unit 530 may supply power to the heating unit 232. Here, the power supplied by the second power supplying unit 520 may be DC power.

The focus ring 240 may be provided in the form of a ring and arranged to surround the edge of the chuck 230. The focus ring 240 serves to control the electric field formed at the edge of the chuck 230. To this end, the focus ring 240 may be formed of a material having a constant dielectric constant.

The ring support 250 may support the focus ring 240 with respect to the base plate 210. By the ring support 250, the focus ring 240 may maintain a constant height with respect to the base plate 210 to maintain a state surrounding the edge of the chuck 230. The ring support 250 may be formed of an insulating material.

As the process by plasma is performed for the substrate W, etching of the focus ring 240 may be performed. As described above, the focus ring 240 adjusts the electric field formed at the edge of the chuck 230 while having a constant dielectric constant. When the focus ring 240 is etched, the overall dielectric constant is changed to change the shape of the electric field. The electric field may determine the direction of the plasma entering the substrate W. As the shape of the electric field is changed, the direction of the plasma entering the substrate W is changed, and the correct process for the substrate W may not be performed. The focus ring 240 that does not form the correct electric field may be replaced with a new focus ring 240.

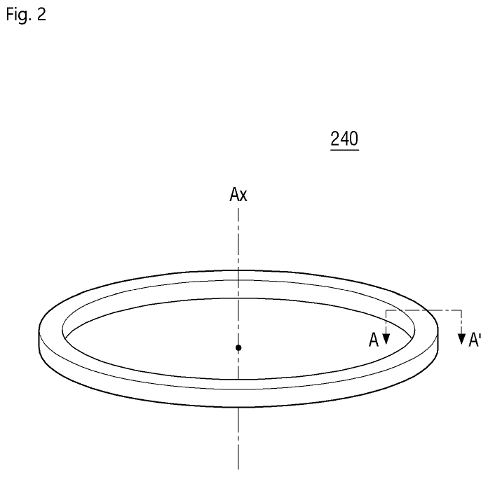

The focus ring 240 according to an embodiment of the present invention may include a plurality of layers having different properties. Here, a bonding surface between the plurality of layers may be formed in a predetermined pattern. The bonding surface between the plurality of layers may be determined in a direction to mitigate changes of an electric field that changes as the focus ring 240 is etched. For example, when the upper layer is removed by etching, the height-reduced focus ring 240 may form an electric field similar to the previous one. A detailed description of the focus ring 240 will be described later with reference to FIGS. 2 to 7.

The shower head 300 serves to spray process gas for the process for the substrate W to the substrate W. The shower head 300 may be arranged in the upper part of the treating space 101. The process gas sprayed from the shower head 300 is sprayed in a downward direction to reach the substrate W.

In the present invention, the process gas used for treating of the substrate W may include a first process gas GS1 and a second process gas GS2. The first process gas GS1 and the second process gas GS2 may be entered into the treating space 101 through the process gas inlet 110. The first inlet line 111 and the second inlet line 112 may be connected to the process gas inlet 110. The first process gas GS1 moves through the first inlet line 111 and enters into the treating space 101, and the second process gas GS1 moves through the second inlet line 112 and enters into treating space 101.

The first process gas GS1 and the second process gas GS2 react with each other and may be sprayed to the substrate W. For example, the first process gas GS1 may serve as a reactive gas, and the second process gas GS2 may serve as a source gas. That is, the first process gas GS1 may activate the second process gas GS2.

The shower head 300 may spray the first process gas GS1 and the second process gas GS2 to the substrate W. The first process gas GS1 and the second process gas GS2 may be sequentially sprayed. After the first process gas GS1 and the second process gas GS2 are sprayed from the shower head 300, they may collide and react with each other. Then, the second process gas GS2 activated by the first process gas GS1 reaches the substrate W and performs process treating for the substrate W. For example, the activated second process gas GS2 may be deposited as a thin film on the substrate W.

The shower head 300 includes an electrode plate 310, a spray unit 320, and an annular dielectric plate 330. The electrode plate 310 may receive RF power. RF power may be provided by the first power supplying unit 510. The electrode plate 310 may be arranged such that one side of its wide surface is in close contact with the inner upper surface of the process chamber 100.

The spray unit 320 is arranged in the lower part of the electrode plate 310 and serves to spray the first process gas GS1 and the second process gas GS2. To this end, the spray unit 320 may include a spray hole SH for spraying the first process gas GS1 and the second process gas GS2. The first process gas GS1 and the second process gas GS2 may penetrate the spray hole SH and be entered into the treating space 101.

The annular dielectric plate 330 serves to electrically separate the electrode plate 310 and the spray unit 320. To this end, the annular dielectric plate 330 is made of a dielectric material and may be provided between the electrode plate 310 and the spray unit 320. The annular dielectric plate 330 may be arranged in an annular shape at an edge between the electrode plate 310 and the spray unit 320. Further, the electrode plate 310 and the spray unit 320 may be spaced apart by a predetermined distance except the edge. Accordingly, a certain space may be formed between the electrode plate 310 and the spray unit 320. Hereinafter, a space formed between the electrode plate 310 and the spray unit 320 is referred to as a diffusion space 102.

The diffusion space 102 may communicate with the spray hole SH. The first process gas GS1 and the second process gas GS2 diffused in the diffusion space 102 may be sprayed to the treating space 101 through the spray hole SH.

When the first power supplying unit 510 supplies RF power to the electrode plate 310, the first process gas GS1 and the second process gas GS2 sprayed to the treating space 101 may be excited to plasma. The first process gas GS1 and the second process gas GS2 may react with each other in an excited state as plasma.

The first gas tank 410 may receive the first process gas GS1, and the second gas tank 420 may receive the second process gas GS2. A first valve V1 may be provided in the first inlet line 111 connecting the first gas tank 410 and the process gas inlet 110, and likewise, a first valve V2 may be provided in the second inlet line 112 connecting the second gas tank 420 and the process gas inlet 110. When process treating is performed for the substrate W, the first valve V1 and the second valve V2 are opened, and the first process gas GS1 and the second process gas GS2 may be injected into the treating space 101 of the process chamber 100. Further, when the process treating for the substrate W is completed, the first valve V1 and the second valve V2 are closed, and the injection of the first process gas GS1 and the second process gas GS2 into the inside of the process chamber 100 may be blocked.

The heater 600 serves to heat the spray unit 320. The first process gas GS1 and the second process gas GS2 injected with the spray unit 320 may be sprayed through the spray hole SH after being heated. As the first process gas GS1 and the second process gas GS2 are heated, mutual reactions may be more actively performed.

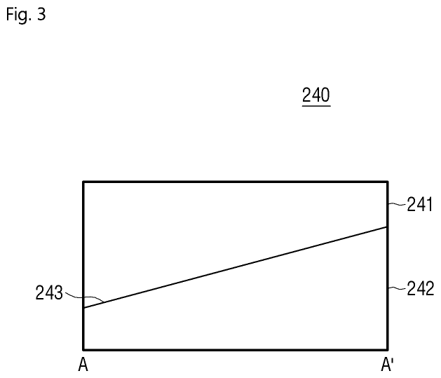

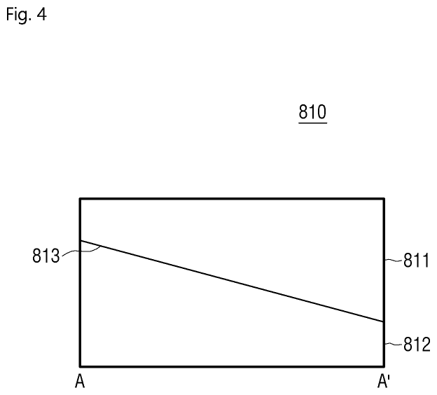

FIG. 2 is a diagram showing a focus ring shown in FIG. 1, FIG. 3 is a diagram showing a cross-section of the focus ring shown in FIG. 2, and FIGS. 4 to 7 are diagrams showing cross-sections of a focus ring according to another embodiment of the present invention.

Referring to FIGS. 2 and 3, the focus ring 240 includes a plurality of layers 241, 242. The plurality of layers may include a protective layer 241 and an electrostatic power generating layer 242.

The protective layer 241 is the top layer of a plurality of layers provided in the focus ring 240 and may be formed of a material having an etching resisting property. For example, the protective layer 241 may be made of a material of silicon carbide (SiC), alumina (Al₂O₃), yttria (Y₂O₃) or aluminum nitride (AlN).

The electrostatic power generating layer 242 is a layer arranged below the top layer and may be made of a material that generates electrostatic power. For example, the electrostatic power generating layer 242 may be made of a material of silicon (Si).

The electrostatic power generating layer 242 may be made of a material having a higher dielectric constant than the protective layer 241. Accordingly, the electrostatic power generating layer 242 may generate a greater electrostatic power compared to the protective layer 241.

The electrostatic power generating layer 242 may be one layer, or may comprise a plurality of layers, as described later. When the electrostatic power generating layer 242 comprises a plurality of layers, each layer may have a different dielectric constant.

The bonding surface 243 of the protective layer 241 and the electrostatic power generating layer 242 may be formed in a predetermined pattern. Specifically, the bonding surface 243 of the protective layer 241 and the electrostatic power generating layer 242 has a shape inclined with respect to the ground, and may be a flat surface. The thicknesses of the protective layer 241 and the electrostatic power generating layer 242 may change as they move away from the substrate W. The bonding surface 243 may be formed to be inclined with respect to the ground so that the thickness of the protective layer 241 decreases as it moves away from the substrate W, and the thickness of the electrostatic power generating layer 242 increases as it moves away from the substrate W.

In the present invention, the focus ring 240 may have a shape of a ring surrounding the central axis Ax. The focus ring 240 may be seated on a seating surface perpendicular to the central axis Ax. For example, the above-described ring support 250 may provide a seating surface perpendicular to the central axis Ax. The ground, which will be described later, represents a seating surface provided by the ring support 250 or a surface parallel to the seating surface.

Referring to FIG. 4, the focus ring 810 includes a plurality of layers 811, 812. The plurality of layers may include a protective layer 811 and a electrostatic power generating layer 812.

The bonding surface 813 of the protective layer 811 and the electrostatic power generating layer 812 has a shape inclined with respect to the ground and may be flat surface. The thicknesses of the protective layer 811 and the electrostatic power generating layer 812 may change as they move away from the substrate W. The bonding surface 813 may be formed to be inclined with respect to the ground so that the thickness of the protective layer 811 increases as it moves away from the substrate W and the thickness of the electrostatic power generating layer 812 decreases as it moves away from the substrate W.

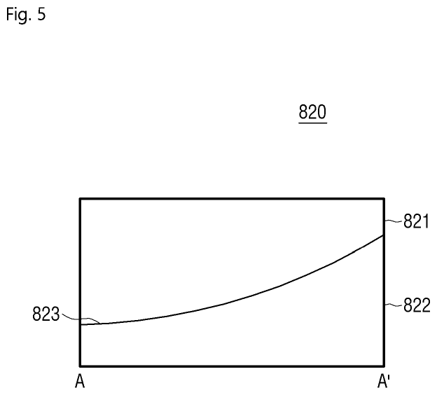

Referring to FIG. 5, the focus ring 820 includes a plurality of layers 821, 822. The plurality of layers may include a protective layer 821 and an electrostatic power generating layer 822.

The bonding surface 823 of the protective layer 821 and the electrostatic power generating layer 822 has a shape inclined with respect to the ground, and may be a curved surface. The bonding surface 823 may have a convex shape with respect to the ground. The thicknesses of the protective layer 821 and the electrostatic power generating layer 822 may change as they move away from the substrate W. The bonding surface 823 may be formed to be inclined with respect to the ground so that the thickness of the protective layer 821 decreases as it moves away from the substrate W and the thickness of the electrostatic power generating layer 822 increases as it moves away from the substrate W.

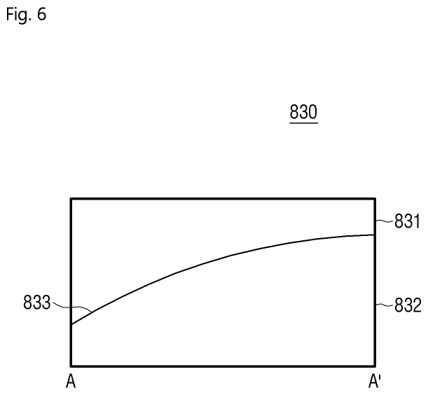

Referring to FIG. 6, the focus ring 830 includes a plurality of layers 831, 832. The plurality of layers may include a protective layer 831 and an electrostatic power generating layer 832.

The bonding surface 833 of the protective layer 831 and the electrostatic power generating layer 832 has a shape inclined with respect to the ground, and may be a curved surface. The bonding surface 833 may have a concave shape with respect to the ground. The thicknesses of the protective layer 831 and the electrostatic power generating layer 832 may change as they move away from the substrate W. The bonding surface 833 may be formed to be inclined with respect to the ground so that the thickness of the protective layer 831 decreases as it moves away from the substrate W, and the thickness of the electrostatic power generating layer 832 increases as it moves away from the substrate W.

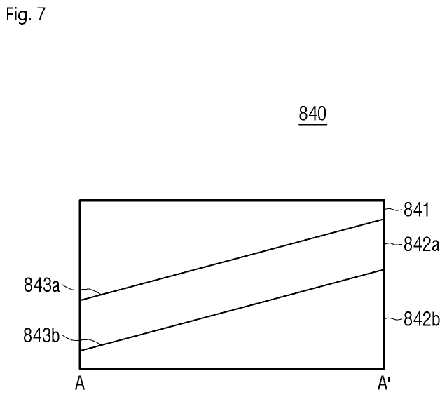

Referring to FIG. 7, the focus ring 840 includes a plurality of layers 841, 842a, and 842b. The plurality of layers may include a protective layer 841 and electrostatic power generating layers 842a and 842b. The electrostatic power generating layers 842a and 842b may include a plurality of layers. The plurality of electrostatic power generating layers 842a and 842b may have different dielectric constants. For example, the electrostatic power generating layer 842a arranged in the lower layer may have a higher dielectric constant than the electrostatic power generating layer 842b arranged in the upper layer.

The bonding surface 843a of the protective layer 841 and the topmost electrostatic power generating layer 842a may have a shape inclined with respect to the ground. The bonding surfaces 843b between the plurality of electrostatic power generating layers 842a and 842b may have a shape inclined with respect to the ground. FIG. 7 shows that each of the bonding surfaces 843a and 843b is a flat surface, but according to some embodiments of the present invention, each bonding surface may be a curved surface.

The thicknesses of the protective layer 841 and the electrostatic power generating layers 842a and 842b may change as they move away from the substrate W. FIG. 7 shows that each bonding surface 843a, 843b is formed to be inclined with respect to the ground so that the thickness of the protective layer 841 decreases as it moves away from the substrate W and the thickness of each electrostatic power generating layer 842a, 842b increases as it moves away from the substrate W. However, according to some embodiments of the present invention, each bonding surface 843a, 843b also may be formed to be inclined with respect to the ground so that the thickness of the protective layer 841 increases as it moves away from the substrate W, and the thickness of each electrostatic power generating layer 842a, 842b decreases as it moves away from the substrate W.

As described above, the number of layers, the pattern of the interlayer bonding surfaces, and the material and dielectric constant of each layer constituting the focus rings 240, 810, 820, 830, and 840 of the present invention can be variously determined according to the process treating environment performing process treating for the substrate W.

Although the embodiments of the present invention have been described with reference to the above and the accompanying drawings, those of ordinary skill in the art to which the present invention pertains can understand that the present invention may be implemented in in other specific forms without changing its technical spirit or essential features. Therefore, it should be understood that the above-described embodiments are illustrative in all respects and not restrictive.

What is claimed is:

1. A substrate treating apparatus comprising:
a process chamber for providing a process treating space for a substrate;
a chuck for supporting the substrate; and
a focus ring arranged to surround an edge of the chuck,
wherein the focus ring includes a plurality of layers having different properties,
wherein a bonding surface between the plurality of layers is formed in a predetermined pattern.

2. The substrate treating apparatus of claim 1,
wherein the plurality of layers comprises,
a protective layer that is a top layer among the plurality of layers and made of a material having an etching resisting property, and
an electrostatic power generating layer that is arranged under the protective layer and made of material generating an electrostatic power.

3. The substrate treating apparatus of claim 2,
wherein the protective layer is made of a material of silicon carbide (SiC), alumina (Al₂O₃), yttria (Y₂O₃) or aluminum nitride (AlN).

4. The substrate treating apparatus of claim 2,
wherein the electrostatic power generating layer is made of a material of silicon (Si).

5. The substrate treating apparatus of claim 2,
wherein the electrostatic power generating layer is made of a material having a higher dielectric constant than the protective layer.

6. The substrate treating apparatus of claim 2,
wherein the electrostatic power generating layer is one layer or includes a plurality of layers having different dielectric constants.

7. The substrate treating apparatus of claim 1,
wherein the bonding surface between the plurality of layers has a shape inclined with respect to the ground.

8. The substrate treating apparatus of claim 7,
wherein the bonding surface has a shape inclined with respect to ground such that a thickness of one of the plurality of layers decreases as it moves away from the substrate, and a thickness of another one of the plurality of layers increases as it moves away from the substrate.

9. The substrate treating apparatus of claim 7,
wherein the bonding surface is a flat surface or a curved surface.

10. A focus ring comprising:
a protective layer that is arranged to surround an edge of a chuck supporting a substrate, has a ring shape, and is made of a material having an etching resisting property; and
an electrostatic power generating layer that is arranged under the protective layer, has a ring shape, and is made of material generating an electrostatic power,
wherein a bonding surface between the protective layer and the electrostatic power generating layer is formed in a predetermined pattern.

11. The focus ring of claim 10,
wherein the protective layer is made of a material of silicon carbide (SiC), alumina (Al₂O₃), yttria (Y₂O₃), or aluminum nitride (AlN).

12. The focus ring of claim 10,
wherein the electrostatic power generating layer is made of a material of silicon (Si).

13. The focus ring of claim 1,
wherein the electrostatic power generating layer is made of a material having a higher dielectric constant than the protective layer.

14. The focus ring of claim 11,
wherein the electrostatic power generating layer is one layer or includes a plurality of layers having different dielectric constants.

15. The focus ring of claim 1,
wherein the bonding surface has a shape inclined with respect to the ground.

16. The focus ring of claim 15,
wherein the bonding surface has a shape inclined with respect to ground such that a thickness of one of the protective layer and the electrostatic power generating layer decreases as it moves away from the substrate, and a thickness of another one of the protective layer and the electrostatic power generating layer increases as it moves away from the substrate.

17. The focus ring of claim 15,
wherein the bonding surface is a flat surface or a curved surface.

18. A substrate treating apparatus comprising:
a process chamber for providing a process treating space for a substrate;
a chuck for supporting the substrate; and
a focus ring arranged to surround an edge of the chuck,
wherein the focus ring includes a plurality of layers having different properties,
wherein a bonding surface between a plurality of layers has a shape inclined with respect to ground so as to be determined in a direction to mitigate change of an electric field that changes as the focus ring is etched.

19. The substrate treating apparatus of claim 18,
wherein the bonding surface has a shape inclined with respect to ground such that a thickness of one of the plurality of layers decreases as it moves away from the substrate, and a thickness of another one of the plurality of layers increases as it moves away from the substrate.

20. The substrate treating apparatus of claim 18,
wherein the bonding surface is a flat surface or a curved surface.
